(19) United States
(12) Patent Application Publication
(10) Pub. No.: US 2011/0002103 A1
(43) Pub. Date: Jan. 6, 2011

(54) Interlocking Structure For Memory Heat Sink

(75) Inventor: Wen-Yi Lee, Taipei Hsien (TW)

Correspondence Address: Wen-Yi Lee, P.O.Box 34-150, Taipei, omitted

(73) Assignee: Wen-Yi Lee, Taipei Hsien (TW)

(21) Appl. No.: 12/495,809

(22) Filed: Jul. 1, 2009

(51) Int. Cl. H05K 7/20

(52) U.S. Cl. 361/704

(57) ABSTRACT

An interlocking structure is arranged on two separable heat dissipating plates that together form a memory heat sink, and includes two elongated flanges, at least two locating tabs, at least one catch tab, at least one expanded head portion, at least one retaining slot in a number corresponding to the expanded head portion, and at least one stopper. Two sets of the interlocking structure are diagonally symmetrically provided near two opposite ends of the two heat dissipating plates. Once the expanded head portions have been extended through the retaining slots and the two heat dissipating plates are outward turned relative to each other, the locating tabs and the expanded head portions will firmly hook to the stoppers and the catch tabs, respectively, without the risk of separating from the retaining slots due to turning open or close, vibrating, or impacting of the two heat dissipating plates.

### BACKGROUND OF THE INVENTION

1. Field of the Invention

The present invention relates to an interlocking structure for memory heat sink, and more particularly to an interlocking structure for conveniently and firmly locking two heat dissipating plates of a memory heat sink to each other.

2. Description of the Prior Arts

The currently available computers have largely increased computing speed and upgraded operation efficiency. However, the increased computing speed and upgraded operation efficiency also brings the problem of high amount of heat produced by the electronic elements in the computer during the operation thereof. The produced heat usually requires an additional heat dissipating device to remove it from the computer.

One of the currently very common means adopted by the computer industrial field to remove the operation-produced heat is to mount a heat sink to the memory module in the computer. According to a conventional memory heat sink technique, two heat dissipating plates are first connected along two adjacent edges thereof, and then outward turned about the connected edges to an open state with an angle contained between them, so as to position a memory module between the two heat dissipating plates. When the user intends to position the memory module between the two connected heat dissipating plates, he or she has to hold the memory module with one hand and the two pivotally opened heat dissipating plates with the other hand. However, the two heat dissipating plates are not exactly hooked to each other. In the process of mounting the memory module, when the two heat dissipating plates are subjected to an external force, vibration and the like, they will easily become separated from each other. This will no doubt cause inconveniences to the user when trying to position the memory module between the two heat dissipating plates.

### SUMMARY OF THE INVENTION

A primary object of the present invention is to provide an interlocking structure for memory heat sink to overcome the problems in positioning the memory module between the two heat dissipating plates of the conventional memory heat sink.

To achieve the above and other objects, the interlocking structure for memory heat sink according to a preferred embodiment of the present invention is provided on a first and a second heat dissipating plates that together form the memory heat sink, and includes:

a first and a second elongated flanges being respectively formed along one of two opposite longer edges of the first and the second heat dissipating plates to generally perpendicularly extend from the longer edge by a predetermined distance;

at least two locating tabs being formed at and forward projected from a front edge of the first elongated flange on the first heat dissipating plate; the two locating tabs being spaced from each other to thereby define a clamping space therebetween; and the locating tabs each being connected to the front edge of the first elongated flange via a downward and forward inclined root portion;

at least one catch tab being formed at and forward projected from a front edge of the second elongated flange on the second heat dissipating plate; and the catch tab being connected to the front edge of the second elongated flange via a downward and forward inclined root portion;

at least one expanded head portion being formed at a front end of one of the locating tabs to project from at least one lateral side thereof and correspond to the catch tab;

at least one retaining slot being formed on the root portion of the catch tab and configured corresponding to the expanded head portion, allowing the expanded head portion to extend therethrough, and the retaining slot being in a number corresponding to that of the expanded head portion; and

at least one stopper being formed on a front end of the catch tab to sidewardly project from at least one side thereof to correspond to one of the locating tabs.

In practically using the present invention, two sets of the interlocking structure are diagonally symmetrically provided near two opposite ends of the first and second heat dissipating plates. To interlock the first and second heat dissipating plates with each other, first approach them to each other, and extend the expanded head portions formed at the front end of the locating tabs through the retaining slots formed on the catch tabs. Then, push the locating tabs and the catch tabs toward one another, so that the locating tabs and the catch tabs are extended into a lower side of the elongated flanges on the second and the first heat dissipating plate, respectively. At this point, the first and the second heat dissipating plate are primarily correspondingly connected to each other at two pivot points through engagement of the expanded head portions with the retaining slots. Then, outward turn the first and the second heat dissipating plate about the two pivot points to an open state with a certain angle contained between them. At this point, since the two elongated flanges are pressed against each other along their front edges, the expanded head portions are confined in the retaining slots, and the stoppers and the locating tabs interfere with one another, the first and the second heat dissipating plate are firmly interlocked. Moreover, since the expanded head portions have shapes matching that of the retaining slots, it can be ensured that, once the expanded head portions have been extended through the retaining slots and the first and the second heat dissipating plate are outward turned relative to each other, the locating tabs and the expanded head portions will firmly hook to the stoppers and the catch tabs, respectively, without the risk of separating from the retaining slots due to turning open or close, vibrating, or impacting of the first and second heat dissipating plates. The expanded head portions will not move out of the retaining slots unless the first and second heat dissipating plates are pivotally turned from the open state to the original closed position. Therefore, the interlocking structure of the present invention can exactly protect the heat dissipating plates against unexpected separation from each other in the process of positioning a memory module between them.

### BRIEF DESCRIPTION OF THE DRAWINGS

FIG. 1 is a fragmentary exploded perspective view showing an interlocking structure for memory heat sink according to a preferred embodiment of the present invention.

FIGS. 2-1 to 2-3 are top views showing a first applied embodiment of the present invention and some variations thereof.

FIGS. 3-1 to 3-3 show the interlocking manner of the interlocking structure of the present invention.

FIGS. 4-1 to 4-10 are top views showing a second applied embodiment of the present invention and some variations thereof.

FIGS. 5-1 to 5-6 are top views showing a third applied embodiment of the present invention and some variations thereof.

FIGS. 6-1 to 6-6 are top views showing still some other variations of the present invention.

### DETAILED DESCRIPTION OF THE PREFERRED EMBODIMENTS

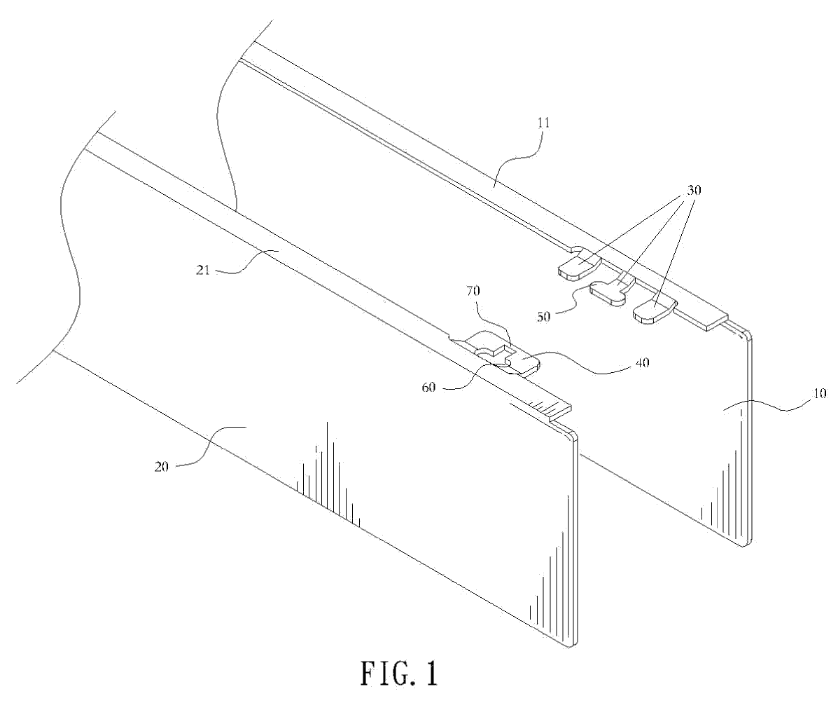

Please refer to FIG. 1. The interlocking structure for memory heat sink according to the present invention is provided on two separable heat dissipating plates that together form a memory heat sink. For the purpose of clarity in describing the present invention, the two similar heat dissipating plates are respectively denoted by a different reference numeral and referred to as a first heat dissipating plate 10 and a second heat dissipating plate 20. In practical implementation, the two heat dissipating plates 10, 20 are two long plates having two opposite longer edges and two opposite shorter edges.

The interlocking structure according to a preferred embodiment of the present invention includes two elongated flanges 11, 21, at least two locating tabs 30, at least one catch tab 40, at least one expanded head portion 50, at least one retaining slot 60 in a number corresponding to that of the expanded head portion 50, and at least one stopper 70. Many different changes can be made to the present invention to provide a number of applied embodiments thereof, some of which will now be described with reference to the accompanying drawings.

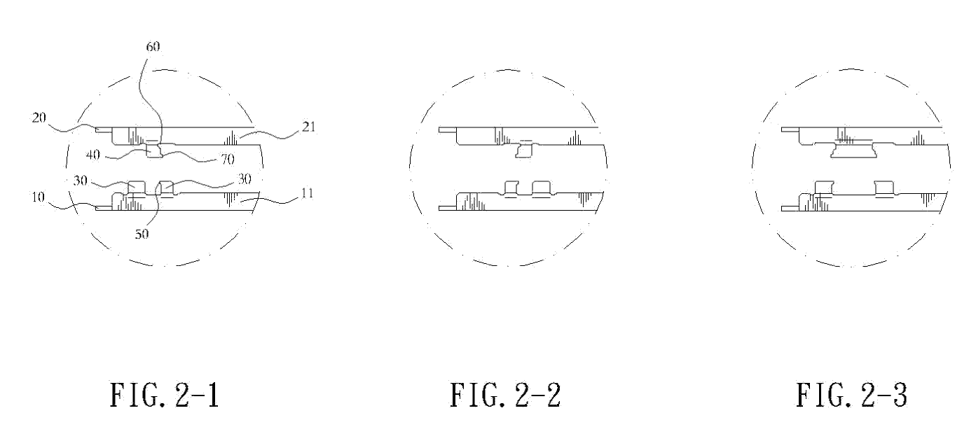

FIG. 2-1 is a top view showing a first applied embodiment of the present invention, in which there are included two elongated flanges 11, 21, two locating tabs 30, one catch tab 40, at least one expanded head portion 50, at least one retaining slot 60 in a number corresponding to that of the expanded head portion 50, and at least one stopper 70.

The elongated flanges 11, 21 are respectively formed along one of the longer edges of the first and second heat dissipating plates 10, 20 to generally perpendicularly extend from the longer edge by a predetermined distance. The elongated flanges 11, 21 can be formed by known skill. When the first and the second heat dissipating plate 10, 20 are connected at the longer edges with the elongated flanges 11, 21 formed thereat and then pivotally turned relative each other to an open position with an angle contained therebetween, the two elongated flanges 11, 21 are abutted on each other along their free edges to thereby prevent the two heat dissipating plates 10, 20 from being further turned open. That is, the two elongated flanges 11, 21 serve to limit the angle by which the two heat dissipating plates 10, 20 can be pivotally turned open relative to each other.

The locating tabs 30 are formed at and forward projected from a front edge of the elongated flange 11 on the first heat dissipating plate 10. The two locating tabs 30 are spaced from each other to thereby define a clamping space between them. Moreover, the locating tabs 30 each are connected to the front edge of the elongated flange 11 via a downward and forward inclined root portion.

The catch tab 40 is formed at and forward projected from a front edge of the elongated flange 21 on the second heat dissipating plate 20. The catch tab 40 is located on the elongated flange 21 at a position corresponding to the clamping space defined between the two locating tabs 30. Moreover, the catch tab 40 is connected to the front edge of the elongated flange 21 via a downward and forward inclined root portion.

The expanded head portion 50 is formed at a front end of one of the locating tabs 30 to project from one lateral side of the front end of the locating tab 30 and correspond to the catch tab 40.

The retaining slot 60 is formed on the root portion of the catch tab 40 and configured corresponding to the expanded head portion 50, allowing the expanded head portion 50 to extend therethrough.

The stopper 70 is transversely projected from one lateral side of a front end of the catch tab 40 to correspond to one of the locating tabs 30.

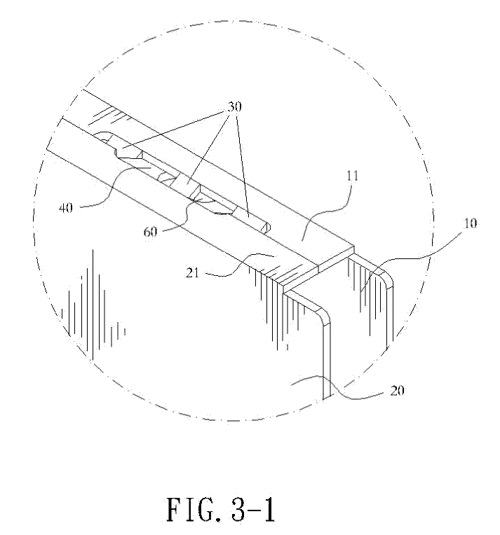

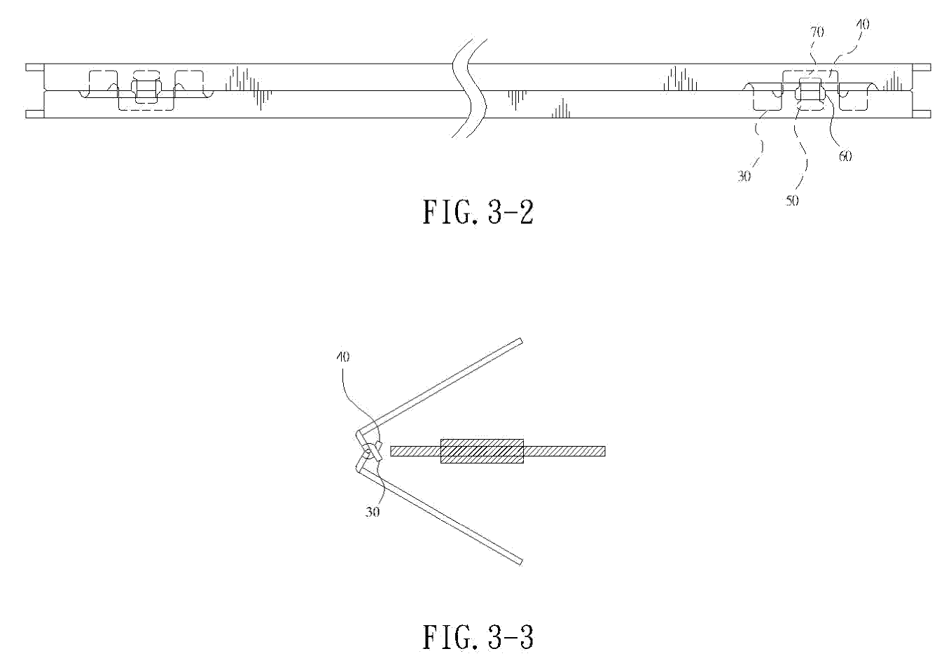

In the first applied embodiment, the expanded head portion 50, the retaining slot 60 and the stopper 70 can be changed in their quantity and extending direction to provide some variations thereof. FIGS. 2-2 and 2-3 are top views of two variations of the first applied embodiment of the present invention. These changes in the described first applied embodiment can be carried out without departing from the scope and the spirit of the invention that is intended to be limited only by the appended claims.

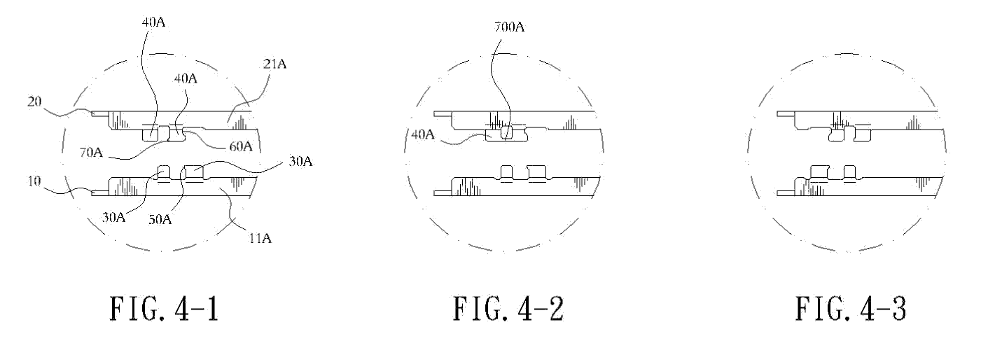

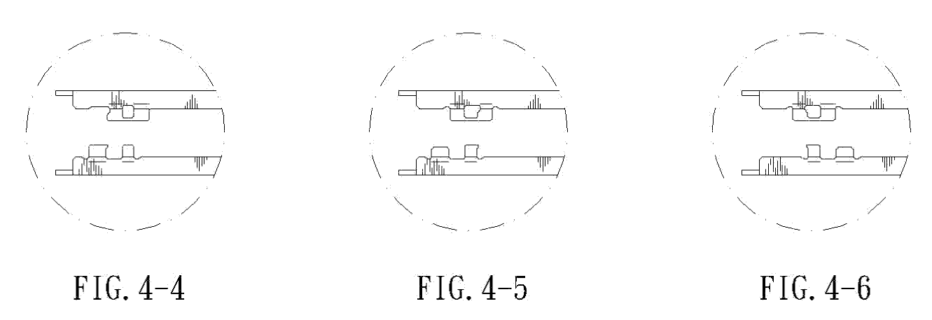

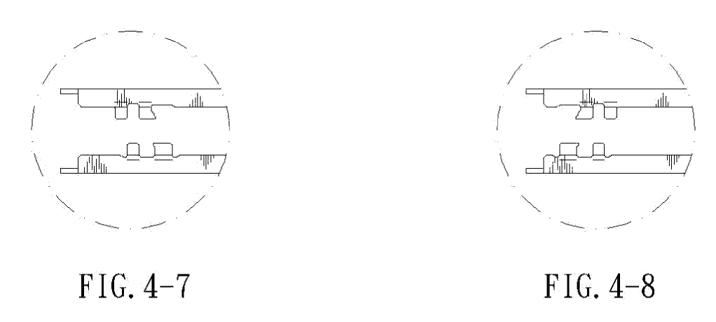

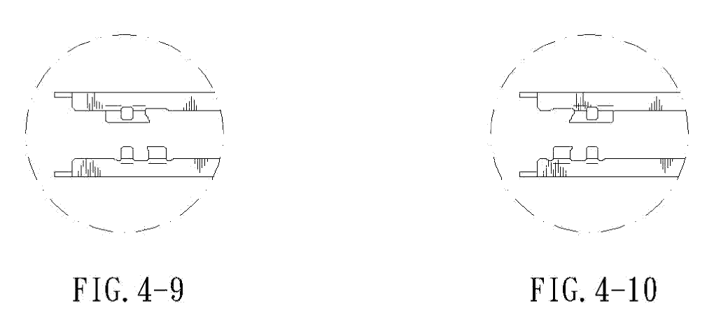

Please further refer to FIG. 4-1 that is a top view showing a second applied embodiment of the present invention, in which there are included two elongated flanges 11A, 21A, two locating tabs 30A, two catch tabs 40A, at least one expanded head portion 50A, at least one retaining slot 60A in a number corresponding to that of the expanded head portion 50A, and at least one stopper 70A.

The two elongated flanges 11A, 21A are arranged in the same manner as that in the first applied embodiment, and are therefore not described repeatedly.

The two locating tabs 30A are formed at and forward projected from a front edge of the elongated flange 11A on the first heat dissipating plate 10. The two locating tabs 30A are spaced from each other to thereby define a clamping space between them. Moreover, the locating tabs 30A each are connected to the front edge of the elongated flange 11A via a downward and forward inclined root portion.

The two catch tabs 40A are formed at and forward projected from a front edge of the elongated flange 21A on the second heat dissipating plate 20. The catch tabs 40A are spaced on the elongated flange 21A to define a clamping space therebetween. The clamping space between the two catch tabs 40A is located corresponding to a first one of the two locating tabs 30A, so that the two catch tabs 40A can cooperatively clamp two lateral sides of the first locating tab 30A. Moreover, a first one of the two catch tabs 40A is located corresponding to the clamping space between the two locating tabs 30A, and the two catch tabs 40A each are connected to the front edge of the elongated flange 21A via a downward and forward inclined root portion.

The expanded head portion 50A is formed at a front end of a second one of the locating tabs 30A to project from one lateral side thereof and correspond to the first catch tab 40A.

The retaining slot 60A is formed on the root portion of the first catch tab 40A and configured corresponding to the expanded head portion 50A, allowing the expanded head portion 50A to extend therethrough.

The stopper 70A is transversely projected from one lateral side of a front end of the first catch tab 40A to correspond to the first locating tab 30A. Alternatively, in a variation of the second applied embodiment of the present invention as shown in FIG. 4-2, there can be provided a stopper 700A that is transversely extended between and connected to the front ends of the two catch tabs 40A.

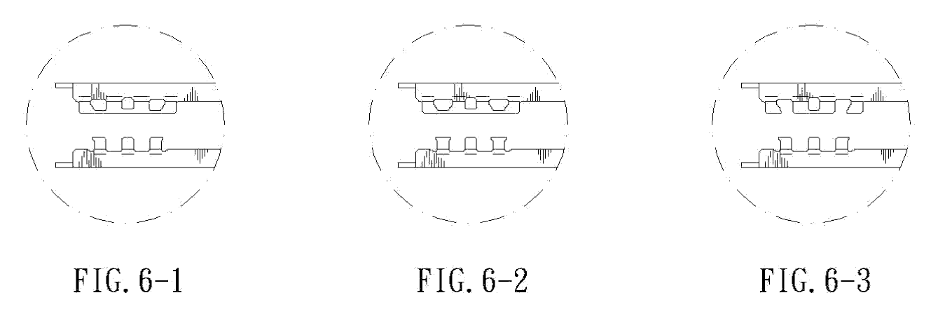

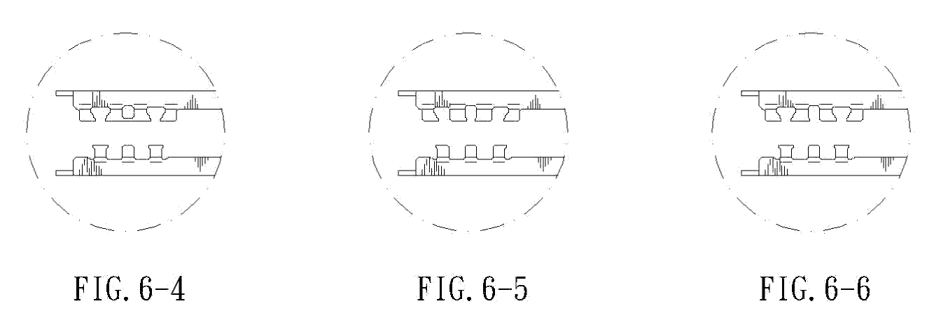

In the second applied embodiment, the expanded head portion 50A, the retaining slot 60A and the stopper 70A can be changed in their quantity and extending direction to provide some other variations thereof. FIGS. 4-3 to 4-10 are top views of some other available variations of the second applied embodiment of the present invention. These changes in the described second applied embodiment can be carried out without departing from the scope and the spirit of the invention that is intended to be limited only by the appended claims.

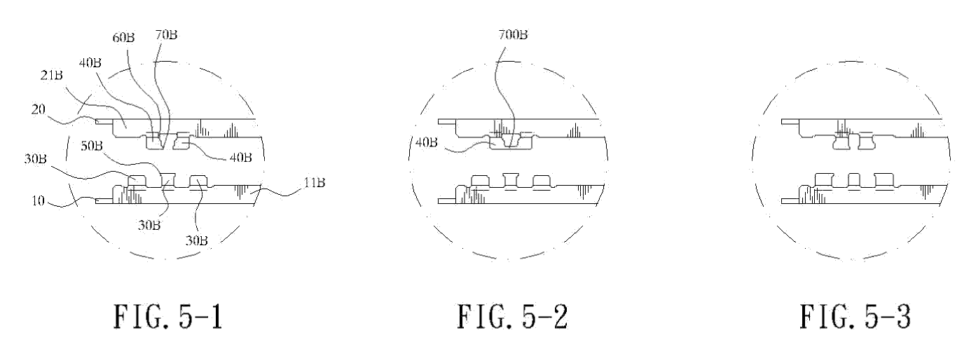

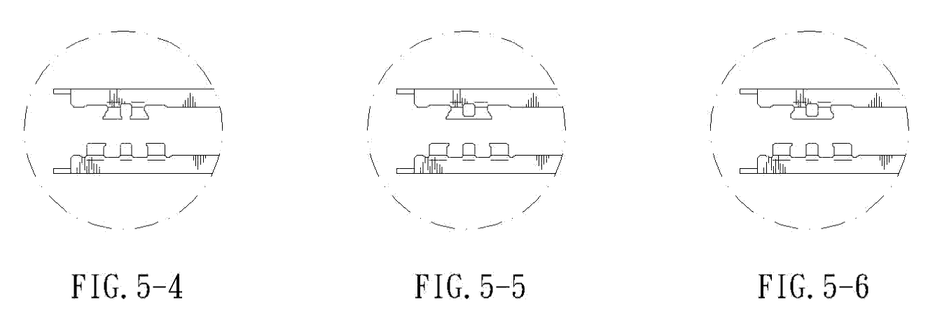

FIG. 5-1 shows a third applied embodiment of the present invention, in which there are included two elongated flanges 11B, 21B, three locating tabs 30B, two catch tabs 40B, at least one expanded head portion 50B, at least one retaining slot 60B in a number corresponding to that of the expanded head portion 50B, and at least one stopper 70B.

The two elongated flanges 11B, 21B are arranged in the same manner as that in the first and second applied embodiments, and are therefore not described repeatedly.

The three locating tabs 30B are formed at and forward projected from a front edge of the elongated flange 11B on the first heat dissipating plate 10. The three locating tabs 30B are spaced from each other to thereby define two clamping spaces among them. Moreover, the locating tabs 30B each are connected to the front edge of the elongated flange 11B via a downward and forward inclined root portion.

The two catch tabs 40B are formed at and forward projected from a front edge of the elongated flange 21B on the second heat dissipating plate 20. The two catch tabs 40B are spaced on the elongated flange 21B to align with the two clamping spaces defined among the three locating tabs 30B. Moreover, the two catch tabs 40A each are connected to the front edge of the elongated flange 21B via a downward and forward inclined root portion.

The expanded head portion 50B is formed at a front end of one of the locating tabs 30B, such as a middle one thereof, to project from one lateral side of the middle locating tab 30B corresponding to a first one of the two catch tabs 40B.

The retaining slot 60B is formed on the root portion of the first catch tab 40B and configured corresponding to the expanded head portion 50B, allowing the expanded head portion 50B to extend therethrough.

The stopper 70B is transversely projected from one lateral side of a front end of the first catch tab 40B to correspond to the middle locating tab 30B. Alternatively, in a variation of the third applied embodiment of the present invention as shown in FIG. 5-2, there can be provided a stopper 700B that is transversely extended between and connected to the front ends of the two catch tabs 40B.

In the third applied embodiment, the expanded head portion 50B, the retaining slot 60B and the stopper 70B can be changed in their quantity and extending direction to provide some other variations thereof. FIGS. 5-3 to 5-6 are top views of some other available variations of the third applied embodiment of the present invention. These changes in the described third applied embodiment can be carried out without departing from the scope and the spirit of the invention that is intended to be limited only by the appended claims.

Please refer to FIGS. 3-1 to 3-3. In practically using the present invention, two sets of the interlocking structure are diagonally symmetrically provided near two opposite ends of the first and second heat dissipating plates 10, 20. To interlock the first and second heat dissipating plates 10, 20 shown in FIG. 1 with each other, first approach them to each other, and extend the expanded head portions 50 formed at the front end of the locating tabs 30 through the retaining slots 60 formed on the catch tabs 40. Then, push the locating tabs 30 and the catch tabs 40 toward one another, so that the locating tabs 30 and the catch tabs 40 are extended into a lower side of the elongated flange 21 and the elongated flange 11, respectively. At this point, the first and the second heat dissipating plate 10, 20 are primarily correspondingly connected to each other at two pivot points through engagement of the expanded head portions 50 with the retaining slots 60. Then, outward turn the first and the second heat dissipating plate 10, 20 about the two pivot points to an open state with a certain angle contained between them. At this point, since the two elongated flanges 11, 21 are abutted against each other along their front edges, the expanded head portions 50 are confined in the retaining slots 60, and the stoppers 70 and the locating tabs 30 interfere with one another, the first and the second heat dissipating plate 10, 20 are firmly interlocked. Moreover, since the expanded head portions 50 have shapes matching that of the retaining slots 60, it can be ensured that, once the expanded head portions 50 have been extended through the retaining slots 60 and the first and the second heat dissipating plate 10, 20 are outward turned relative to each other, the locating tabs 30 and the expanded head portions 50 will firmly hook to the stoppers 70 and the catch tabs 40, respectively, without the risk of separating from the retaining slots 60 due to turning open or close, vibrating, or impacting of the first and second heat dissipating plates 10, 20. The expanded head portions 50 will not move out of the retaining slots 60 unless the first and second heat dissipating plates 10, 20 are pivotally turned from the open state to the original closed position. Therefore, the interlocking structure of the present invention can exactly protect the heat dissipating plates 10, 20 against unexpected separation from each other in the process of positioning a memory module between them.

In the present invention, in addition to the above-described first, second and third applied embodiments, the locating tabs 30, the catch tabs 40, the expanded head portion 50, the retaining slot 60 and the stopper 70 can be changed in their quantity to provide more different applied embodiments, such as those shown in FIGS. 6-1 to 6-6. However, while these changes bring different appearances to the applied embodiments, they can be carried out without departing from the scope and the spirit of the invention that is intended to be limited only by the appended claims.

What is claimed is:

1. An interlocking structure for memory heat sink, the memory heat sink consisting of a first and a second heat dissipating plate, on which the interlocking structure is provided; the interlocking structure comprising:
a first and a second elongated flanges being respectively formed along one of two opposite edges of the first and the second heat dissipating plates to generally perpendicularly extend from the edge by a predetermined distance;
at least two locating tabs being formed at and forward projected from a front edge of the first elongated flange on the first heat dissipating plate; the two locating tabs being spaced from each other to thereby define a clamping space therebetween; and the locating tabs each being connected to the front edge of the first elongated flange via a downward and forward inclined root portion;
at least one catch tab being formed at and forward projected from a front edge of the second elongated flange on the second heat dissipating plate; and the catch tab being connected to the front edge of the second elongated flange via a downward and forward inclined root portion;
at least one expanded head portion being formed on one of the locating tabs to project from at least one lateral side thereof and correspond to the catch tab;
at least one retaining slot being formed on the catch tab and configured corresponding to the expanded head portion, allowing the expanded head portion to extend therethrough; and the retaining slot being in a number corresponding to that of the expanded head portion; and
at least one stopper being formed on the catch tab to sidewardly project therefrom to correspond to one of the locating tabs.

2. The interlocking structure for memory heat sink as claimed in claim 1, wherein the number of the locating tabs is two, the number of the catch tab is one, and the catch tab is aligned with the clamping space defined between the two locating tabs.

3. The interlocking structure for memory heat sink as claimed in claim 1, wherein the number of the locating tabs is two, the number of the catch tabs is two, and the two catch tabs are spaced from each other to define a clamping space therebetween; the clamping space defined between the two catch tabs being aligned with a first one of the locating tabs, and the clamping space defined between the two locating tabs being aligned with a first one of the catch tabs.

4. The interlocking structure for memory heat sink as claimed in claim 1, wherein the number of the locating tabs is three, the number of the catch tabs is two, and the three locating tabs are spaced from each other to define two clamping spaces among them; and the two catch tabs being separately aligned with the two clamping spaces defined among the three locating tabs.

5. The interlocking structure for memory heat sink as claimed in claim 1, wherein there is a plurality of the catch tabs, and the at least one stopper is extended between and connected to two adjacent ones of the catch tabs.

6. The interlocking structure for memory heat sink as claimed in claim 1, wherein the expanded head portion is formed at a front end of the locating tab to project from at least one lateral side thereof; the retaining slot is formed on the root portion of the catch tab; and the stopper is formed at a front end of the catch tab to sidewardly project from at least one lateral side thereof.
